(19) United States
(12) Patent Application Publication
(10) Pub. No.: US 2009/0236659 A1
(43) Pub. Date: Sep. 24, 2009

(54) ISOLATION STRUCTURE FOR SEMICONDUCTOR DEVICE WITH MULTIPLE TERMINALS

(75) Inventors: Mark A. Gajda, Stockport (GB); Ian Kennedy, Stockport (GB); Adam R. Brown, Bramhall (GB); James B. Parkin, Chapel-En-Le-Frith (GB)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/299,917

(22) PCT Filed: May 2, 2007
(86) PCT No.: PCT/IB2007/051642

§ 371 Date: Nov. 7, 2008

(30) Foreign Application Priority Data
May 8, 2006 (EP) 06113646.1

(51) Int. Cl. H01L 29/78; H01L 21/77; H01L 21/762

(52) U.S. Cl. 257/334; 438/270; 257/E29.257; 257/E21.598; 257/E21.546

(57) ABSTRACT

A semiconductor device has a first region (10) and a second region (20), gate trenches (50) being formed in paid first and second regions including insulated gates to control conduction between source regions (42) and a common drain region (40) through a body region separated into first (34) and second (36) body regions. Isolation between the first and second regions is provided in a simple way by providing a gap between the first and second body regions (34,36) formed by eg. at least one trench (52) or a part of the drain region.

The invention relates to a semiconductor devices with multiple terminals, in particular to semiconductor devices with multiple source terminals and/or multiple gates.

Semiconductor field effect transistors (FETs) include, in particular, single devices which may be used in power applications.

Multiple FETs can be included on a common substrate for a number of reasons. These need to be separated to ensure that they are electrically isolated from one another, and this is achieved using isolation structures. Such structures may be used in a number of applications.

It is not always essential for the structures to be completely isolated from one another, and in structures known as common drain dual devices a common drain is used for multiple transistors, each transistor having a separate source and a separate gate. In general, the common drain is in a conductive semiconductor substrate.

However, even in these devices there is a need for isolation between adjacent devices, and in particular this isolation needs to function even if the load attached to one of the devices develops a short circuit configuration. If, for example, the devices are used between a 14V drain and a 0V source, the device isolation between the sources of adjacent devices needs to be at least 14V. As will be appreciated, the amount of isolation required depends on the application.

One such application is a current sense transistor which has a main transistor part and a current sense part, typically sharing gate and drain contacts with a separate source. The main output is used to drive a load, and the current sense part is used to provide an indication of the load current. If the current sense and main parts are similar, except differently sized, the current sense output current should be a constant fraction of the current output from the main part. Thus, it can be used as a direct measure of the output current.

For the current sense transistor to work as intended, the current sense current should be a constant fraction of the main current, which should vary as little as possible with parameters such as gate voltage, source-drain voltage, or any other transistor.

It is desirable that an unexpected voltage condition in one of the main and sense FETs such as that caused by a short circuit in the load does not create unexpected current in the other.

A prior approach is described in Xiao et al, “Current sensing trench power MOSFET for automotive applications”, APEC 2005, Twentieth annual applied power electronics conference and exposition, pages 766 to 770. In this device, a thick p+ type field isolation is provided between main and sense FETs, with a graded transition layer. However, this periphery is complex to manufacture.

US 2003/0141522 describes a transistor with a separate source sensing function; in an embodiment the N⁺ source dopants are omitted from a region between source and sense contacts, as are the source metallisations. However, although there is no direct connection between source regions in the main and sense transistors, there does not appear to be any isolation at all between main and sense devices apart from this. It therefore appears that the transistor of US 2003/0141522 could not support an unexpected voltage condition in one of the transistors.

There is thus a need for a circuit that combines good isolation, constant ratio of currents between main and sense FETs and ease of manufacture.

According to the invention there is provided a semiconductor device having opposed first and second major surfaces, comprising: a body region of a first conductivity type adjacent to the first major surface wherein the body region is divided into a first body region forming part of a first transistor device in a first region and a second body region forming part of a second transistor device in a second region; a drain region of second conductivity type opposite to the first conductivity type extending from the body region towards the second major surface; a plurality of source regions of second conductivity type at the first major surface; a plurality of gate trenches extending in the first body region and the second body region, the gate trenches including a plurality of insulated gates controlling conduction between the source regions through the body region into the drain region; and an isolation region between the first and second body regions defined by at least one gap interrupting the body region between the first and second body regions to define the isolation region without additional edge termination in the source regions, drain region or body region between the first and second regions.

The semiconductor device provides isolation between two transistor devices such as main and sense FETs while also allowing a constant current ratio between the current delivered from the main FET and the current delivered from the sense FET. The inventors have realised that sufficient isolation can be achieved by a simple interruption or interruptions in the p-type body region between the first and second regions. There is no need for conventional isolation structures such as those proposed by Xiao et al which are much more complex than this.

The easier layout improves manufacturability.

The first and second transistor devices may be main and sense FETs. The structure can deliver very good sense ratio linearity down to low device currents.

In embodiments the isolation region may comprise one or more trenches extending along the boundary between first and second regions and extending from the first major surface through the body region to the drain region.

There may be a plurality of trenches with a pitch in the range 1 μm to 20 μm

There may be one trench extending along the boundary between first and second regions, or a plurality of trenches arranged side by side. In preferred embodiments there may be between eight and twenty trenches.

In other embodiments the first and second body regions are separated by an isolation region of second conductivity type extending from the first major surface through the body region to the drain region.

The width of the isolation region may be in the range 2.5 μm to 8 μm at the first major surface, preferably 2.5 μm to 5 μm.

The isolation region may be in the form of a closed loop at the first major surface enclosing the second body region and with the first body region outside the loop. The isolation structure of the present invention provides sufficient isolation in this configuration.

Embodiments may include an insulated field plate extending over the first major surface over the isolation region.

In an aspect, the invention relates to the use of such a semiconductor device including applying a voltage to the insulated field plate. For convenience, a ground voltage (0V) may be used.

In another aspect, the invention also relates to a method of making the semiconductor device.

For a better understanding of the invention, embodiments will now be described, purely by way of example, with reference to the accompanying drawings, in which:

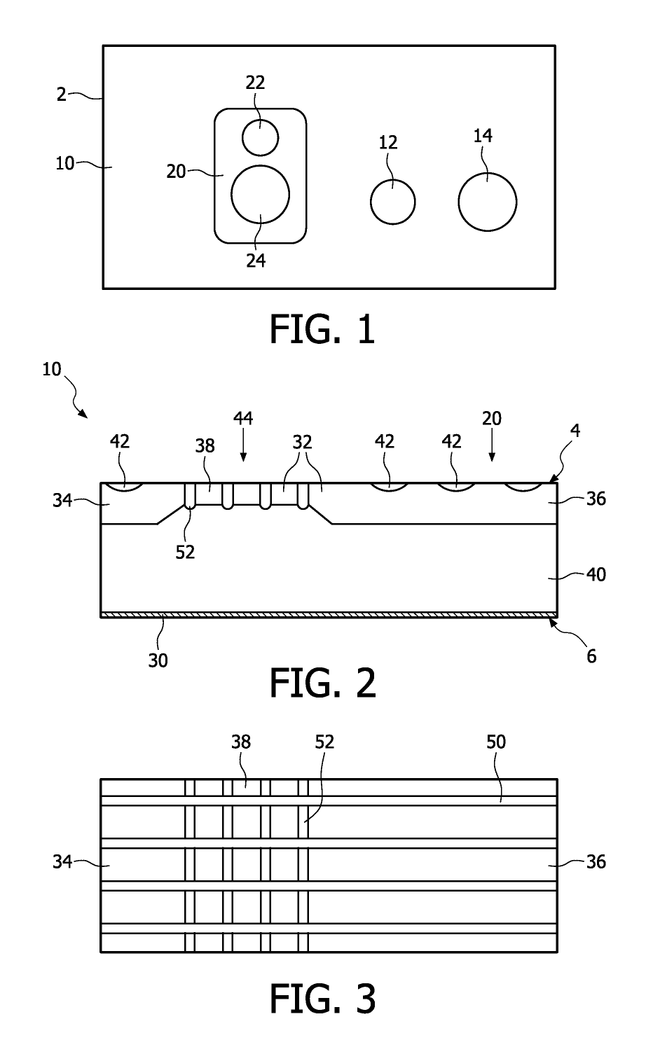

FIG. 1 shows a top view of a first embodiment of the invention;

FIG. 2 shows a detail side section through the arrangement of FIG. 1;

FIG. 3 shows a detail top view of the same part of the arrangement of FIGS. 1 and 2;

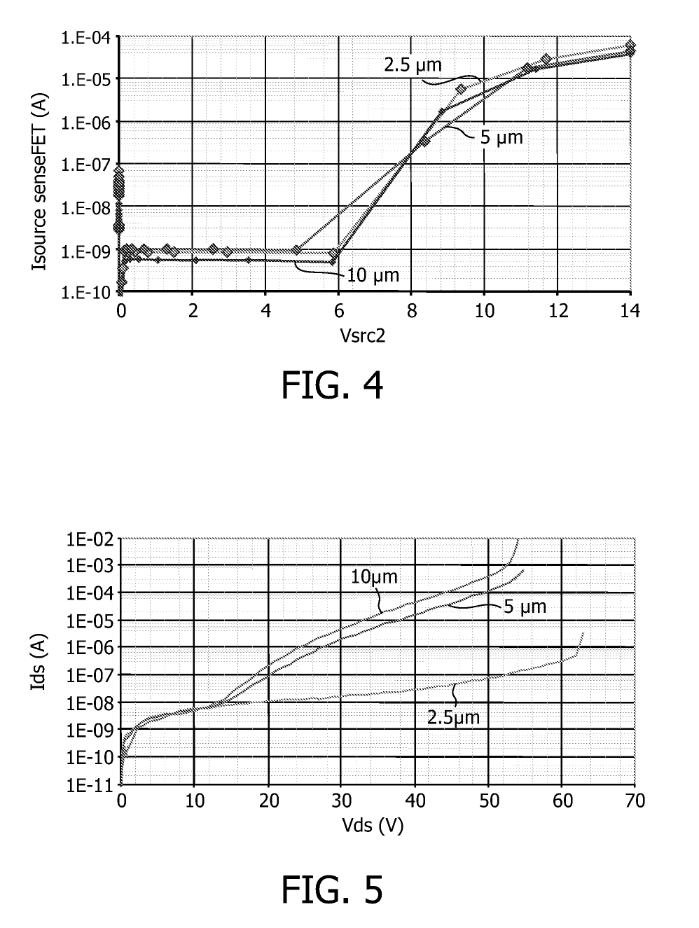

FIG. 4 shows the current through the sense FET of the first embodiment with the FET off as a function of source-drain voltage;

FIG. 5 shows the FET current of the first embodiment with the FET off as a function of source-drain voltage;

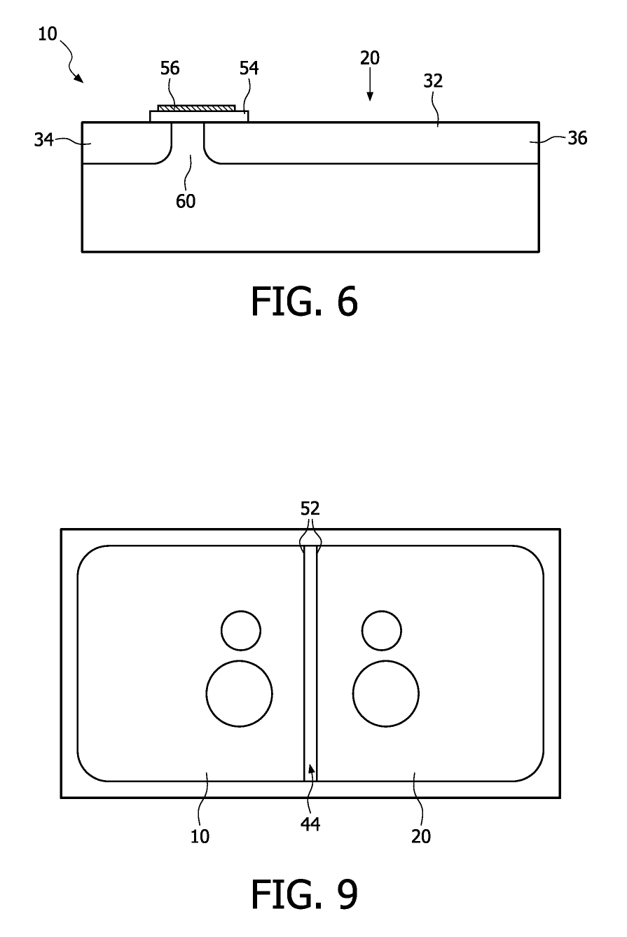

FIG. 6 shows a detail side view of a second embodiment of the invention;

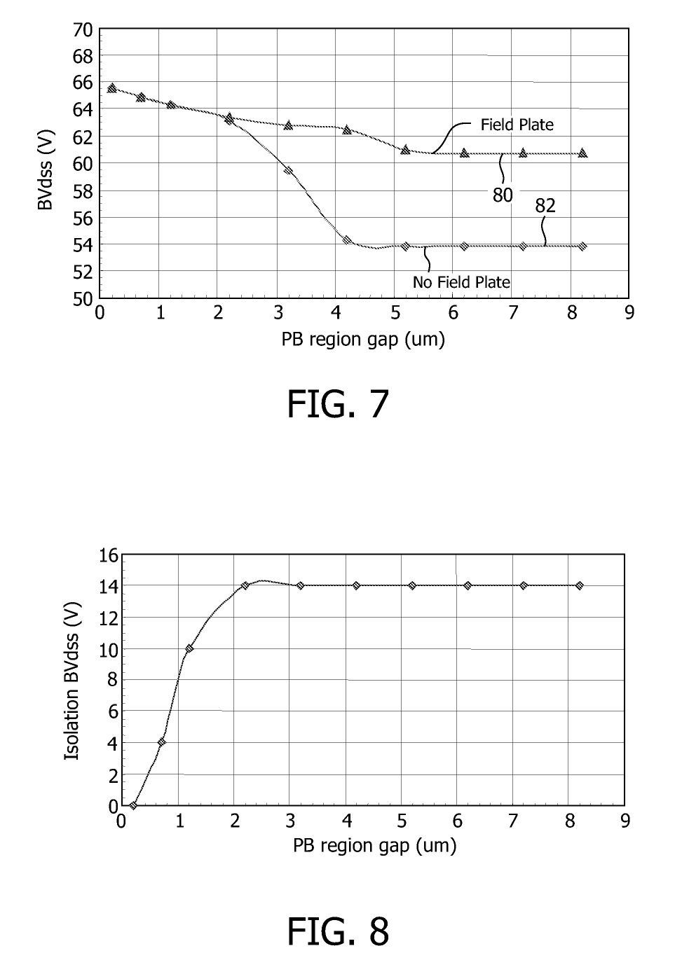

FIG. 7 shows the source drain breakdown voltage in the second embodiment;

FIG. 8 shows the isolation breakdown voltage between main and sense FETs in the second embodiment; and

FIG. 9 shows a top view of a third embodiment of the invention.

The drawings are schematic and not to scale. Like components are given the same reference numerals in the different Figures.

Referring to FIGS. 1 to 3, a semiconductor device including a main FET and a sense FET is described, with a top view in FIG. 1, a detail side section in FIG. 2 and a detail top view in FIG. 3.

FIG. 1 shows a semiconductor device 2 divided into a first region 10 and a second region 20. The first region 10 is a main FET and the second region 20 is a sense FET.

A source contact 12 and a gate contact 14 are provided in the first region 10 and a source contact 22 and gate contact 24 are also provided for the second region 20. The gate contacts 14,24 are connected together so that the gate voltage applied to the first and second regions is the same.

Referring to FIG. 2, a detail view is shown in side section showing the boundary between the main and sense FETs. The view shows opposed first 4 and second 6 major surfaces at the front and rear respectively. A common drain contact 30 is provided on the rear of the substrate (FIG. 2) i.e. on second major surface 6 for both first and second regions 10, 20. FIG. 2 also shows in more detail isolation region 44 between first and second regions 10,20.

A body region 32 is provided at the first major surface 4, divided into a first body region 34 in the first region 10, a second body region 36 in second region 20, and an isolation body region 38 in isolation region 44. The body region 32 is semiconductor doped to be a first conductivity type (n type or p type). Isolation trenches 52 form a number of breaks in the isolation body region 38.

There may be a single implant to form the first, second and isolation body regions 34,36,38 or alternatively two implants may be used, which allows the first and second body regions 34,36 and the isolation body region 38 to have different thicknesses as shown.

In the embodiment, the isolation body region 38 is formed with a plurality of isolation trenches 52 which are formed along the border between first and second regions, as illustrated in FIGS. 2 and 3. In the embodiment described, the pitch of these trenches is about 2.5 μm.

A drain region 40 is below the body region 32 and in the embodiment extends to the second major surface 6. The drain region 40 is conductive and doped to be a second conductivity type opposite to the first conductivity type.

A plurality of source contacts 42 of second conductivity type are also provided at the first major surface. These are connected to source contacts 12, 22 by metallisations (not shown).

Conduction between the source contacts 42 and drain region 40 through body region 32 is controlled by a number of insulated gate trenches 50 running in parallel in both the first and second regions, as illustrated in FIG. 3.

The number of gate contacts 14,24 may depend on the number of gate trenches 50. In this embodiment, the gate trenches 50 and gates are continuous and it may therefore be possible to provide a single gate contact for the gate in both the first and second regions, though in the embodiment separate gate contacts 14, 24 are used.

In alternative embodiments, the isolation trenches 52 can interrupt the gate trenches. In this case, separate gate contacts 14, 24 are used.

The device may be formed by forming the body region 32, for example by implantation in the drain region 40, and then forming isolation trenches 52 to separate the body region and in the same step forming the gate trenches 50. The isolation trenches 52 may be filled with insulator, and insulated gates formed in the gate trenches 50. Thus, the device according to the invention is straightforward to manufacture.

Calculations of the sense FET current in this case have been carried out for pitches 2.5 μm, 5 μm and 10 μm as illustrated in FIG. 4, in each case for four isolation trenches 52 as illustrated in FIGS. 1 to 3. It will be seen that a breakdown voltage of 5 to 6 V is achieved, i.e. the sense FET current is minimal.

Breakdown voltages of 14V can be achieved with a moderate number of isolation trenches 52, approximately nine or ten. Accordingly, a preferred embodiment has at least eight isolation trenches arranged side by side in the isolation region 38.

FIG. 5 illustrates the current as a function of source-drain voltage for the same 2.5 μm, 5 μm and 10 μm pitches. The 2.5 μm pitch achieves a breakdown voltage above 60V.

The approach has a number of benefits. Firstly, the approach avoids the need for a complex edge termination between the first and second regions. This avoids the need for significant area to be taken up by the edge termination, and more importantly it avoids the need for varied topography (varied height) and so helps maintain close electrical matching between the main and sense FETs.

The approach avoids the need for an extra mask since the isolation trenches 52 can be formed in the same step as the gate trenches 50.

In spite of the simplicity suitable isolation can be obtained.

An alternative embodiment is shown in FIG. 6 where the body region 32 has a gap 60 in the body region 32 between first body region 34 in first region 10 and second body region 36 in second region 20. The semiconductor in the gap has the second conductivity type, the same as the drain region 40. The gap can be created with a suitable mask when forming the body region 32. In particular, the body region 32 may be defined in an implantation step using a mask to define the gap 60 without implantation. Thus, drain region 40 effectively extends to the first major surface 4.

An alternative method for creating the gap 60 of second conductivity type is to carry out a further implantation step of dopant of second conductivity type in the gap region to form the gap.

In the embodiment, the gate trenches 50 and the conductive gates in the trenches extend continuously from the first region into the second region without a break. This simplifies manufacture and connects the gates of main and sense transistors together. Alternatively, the trenches may have a break in the isolation region.

A moderately sized gap 60, of width 2.5 μm, achieves the required isolation of 14V.

In this embodiment, an insulation layer 54 of tetra-ethyl orthosilicate (TEOS) is provided over the isolation region 38 and a conductive field plate 56 provided over that. The insulation layer has a thickness of 600 nm. In use, the conductive field plate is kept at 0V. In alternative embodiments, the insulation layer 54 and field plate 56 are omitted.

FIG. 7 shows the breakdown voltage in the main device as a function of the gap width using the field plate 56 at 0V (Curve 80) and without the field plate (curve 82). The calculations assume a p-type body region 32 of depth 7 μm doped to a concentration of 7.83×10¹⁵ cm⁻³.

It will be seen that the use of the field plate allows a greater breakdown voltage, though it is not required.

The isolation breakdown voltage between the main and the sense transistors has been calculated as a function of the gap, using the same assumptions as for FIG. 7. The results are shown in FIG. 8.

It will be seen that a range of widths of 2.5 μm to 10 μm, preferably 2.5 μm to 5 μm is appropriate.

FIG. 9 illustrates a third embodiment in which the invention is applied not to a sense FET but to a dual FET. In this case, the first region 10 forms a first transistor and the second region 20 a second transistor commonly formed on a single substrate. The two transistors are symmetrically formed, and are intended to form a matched pair.

The third embodiment of FIG. 9 uses a number of trenches 52 to form isolation region 44 as in the first embodiment but in an alternative embodiment (not illustrated) the isolation region is formed as in the second embodiment by a simple gap in the body region.

The gate trenches do not extend across the isolation region 44 and separate gate contacts 14,24 are used.

The invention is not limited to the embodiments described above.

The precise form of the transistors in the first and second region may be varied as required. The size and doping levels of the various regions may also be varied as required.

The invention is applicable to both p-type and n-type transistors.

Although a single drain region is described, the drain region may be divided into one or more different regions of different doping concentrations. The drain contact may be provided on the front, not the back, using known techniques.

Those skilled in the art will appreciate that many alternatives are possible although not specifically mentioned.

1. A semiconductor device having opposed first and second major surfaces, comprising:
a body region of a first conductivity type adjacent to the first major surface wherein the body region is divided into a first body region forming part of a first transistor device in a first region and a second body region forming part of a second transistor device in a second region;
a drain region of second conductivity type opposite to the first conductivity type extending from the body region towards the second major surface;
a plurality of source regions of second conductivity type at the first major surface;
a plurality of gate trenches extending in the first body region and the second body region, the gate trenches including a plurality of insulated gates controlling conduction between the source regions through the body region into the drain region; and
an isolation region between the first and second body regions defined by at least one gap interrupting the body region between the first and second body regions to define the isolation region without additional edge termination in the source regions, drain region or body region between the first and second regions.

2. A semiconductor device according to claim 1 wherein the gate trenches extend continuously from the first body region through the isolation region into the second body region.

3. A semiconductor device according to claim 1, wherein the first transistor device is a main FET and the second transistor device is a sense FET.

4. A semiconductor device according to claim 1, wherein the isolation region comprises at least one trench extending along the boundary between first and second regions and extending from the first major surface through the body region to the drain region interrupting the body region to form the at least one gap.

5. A semiconductor device according to claim 4 including a plurality of trenches extending along the boundary between first and second regions with a pitch in the range of about 1 μm to 20 μm.

6. A semiconductor device according to claim 4, wherein there are at least eight trenches arranged side by side extending along the boundary between first and second regions.

7. A semiconductor device according to claim 1, wherein
the first and second body regions are separated by a part of the drain region extending to the first major surface to define the gap.

8. A semiconductor device according to claim 7 wherein the width of the isolation region is in the range of about 2.5 μm to 8 μm at the first major surface.

9. A semiconductor device according to claim 1, wherein isolation region is in the form of a closed loop at the first major surface enclosing the second body region and with the first body region outside the loop.

10. A semiconductor device according to claim 1, further comprising an insulated field plate extending over the first major surface over the isolation region.

11. Use of a semiconductor device according to claim 10 including applying a voltage to the insulated field plate.

12. A method of manufacturing a semiconductor device having first and second transistor regions, comprising:
forming a body region of a first conductivity type at the first major surface of a drain region of second conductivity type opposite to the first conductivity type, and defining the body region to have at least one gap interrupting the body region between the first and second regions to define an isolation region;
forming a plurality of source regions of second conductivity type at the first major surface in both the first and second transistor regions;
forming a plurality of gate trenches extending in the first body region and the second body region, and
filling the trenches with a plurality of insulated gates for controlling conduction between the source regions through the body region into the drain region;
wherein an isolation region between the first and second body regions is defined by the at least one gap interrupting the body region between the first and second body regions to define the isolation region without additional edge termination in the source regions, drain region or body region between the first and second regions.

13. A method according to claim 12 wherein the gate trenches are formed to extend continuously from the first body region through the isolation region into the second body region.

14. A method according to claim 12, wherein defining the body region to have at least one gap comprises forming a plurality of trenches extending along the boundary between first and second regions and extending from the first major surface through the body region to the drain region interrupting the body region to form the at least one gap.

15. A method according to claim 12, wherein defining the body region to have at least one gap consists of implanting the body region leaving a gap between a first body region in the first region and a second body region in the second region.
